(19) United States
(12) Patent Application Publication
(10) Pub. No.: US 2023/0352415 A1
(43) Pub. Date: Nov. 2, 2023

(54) MACROCHIP WITH INTERCONNECT STACK FOR POWER DELIVERY AND SIGNAL ROUTING

(71) Applicant: Broadcom International Pte. Ltd., Singapore (SG)

(72) Inventor: Thomas Dungan, Fort Collins, CO (US)

(73) Assignee: Broadcom International Pte. Ltd., Singapore (SG)

(21) Appl. No.: 17/730,765

(22) Filed: Apr. 27, 2022

(51) Int. Cl. H01L 23/538; H01L 25/065; H01L 23/00; H01L 25/00

(52) U.S. Cl. CPC H01L 23/5386; H01L 25/0652; H01L 24/83; H01L 25/50; H01L 24/16; H01L 24/32; H01L 2224/32145; H01L 2224/16225; H01L 2924/1437; H01L 2924/1436; H01L 2924/1431; H01L 2224/83895; H01L 2924/37001

(57) ABSTRACT

A device may include a host substrate with two or more circuit regions, one or more first stacks electrically connected to the circuit regions, and one or more second stacks providing electrical connections between the circuit regions. At least some of the second stacks may include an insulator wafer bonded to a die, where the die is bonded to at least one of the circuit regions. At least one of the second stacks may include a power distribution pathway to provide the electrical power to at least one of the circuit regions, which may include includes electrically-conductive vias through the insulator wafer and the die or capacitors in the die. Further, the die of at least one of the one or more second stacks may include electrical pathways to provide electrical connections between at least two of the two or more circuit regions.

### TECHNICAL FIELD

The present disclosure relates generally to macrochips and, more particularly, to macrochips with interconnect stacks for signal routing and power delivery.

### BACKGROUND

Many applications including, but not limited to, high-performance computing may benefit from circuits having physical sizes larger than a typical reticle field. However, typical techniques for manufacturing devices larger than a typical reticle field typically suffer from various penalties in complexity, yield, or power constraints that may practically limit the applicability of these techniques. There is therefore a need to develop systems and methods to cure the above deficiencies.

### SUMMARY

A device is disclosed in accordance with one or more illustrative embodiments. In one illustrative embodiment, the device includes a host substrate including two or more circuit regions. In another illustrative embodiment, the device includes one or more first stacks, each of the one or more first stacks including one or more electrical components on one or more layers, and each of the one or more first stacks electrically connected to at least one of the two or more circuit regions on the host substrate. In another illustrative embodiment, the device includes one or more second stacks providing electrical connections between the two or more circuit regions, the one or more second stacks further providing electrical power to the two or more circuit regions. In another illustrative embodiment, at least some of the second stacks include an insulator wafer bonded to a die, where the die is further connected to at least one of the two or more circuit regions. In another illustrative embodiment, at least one of the one or more second stacks includes a first electrical pathway to provide the electrical power to at least one of the two or more circuit regions, the first electrical pathway including an electrically-conductive via through the insulator wafer and at least one of an electrically-conductive via through the die or a capacitor in the die. In another illustrative embodiment, the die of at least one of the one or more second stacks includes one or more second electrical pathways to provide electrical connections between at least two of the two or more circuit regions.

A method is disclosed in accordance with one or more illustrative embodiments. In one illustrative embodiment, the method includes fabricating a host substrate including two or more circuit regions. In another illustrative embodiment, the method includes fabricating one or more first stacks, each of the one or more first stacks including one or more electrical components on one or more layers. In another illustrative embodiment, the method includes connecting the one or more first stacks to at least one of the two or more circuit regions. In another illustrative embodiment, the method includes fabricating one or more second stacks, where at least some of the second stacks include an insulator wafer connected to a die. In another illustrative embodiment, the method includes connecting the one or more second stacks to the host substrate, where at least one of the one or more second stacks includes a first electrical pathway to provide electrical power to at least one of the two or more circuit regions, the first electrical pathway including an electrically-conductive via through the insulator wafer and at least one of an electrically-conductive via through the die or a capacitor in the die. In another illustrative embodiment, at least one of the one or more second stacks includes a second electrical pathway to provide electrical connections between at least two of the two or more circuit regions.

A device is disclosed in accordance with one or more illustrative embodiments. In one illustrative embodiment, the device includes two or more computational nodes. In another illustrative embodiment, at least some of the two or more computational nodes include a host substrate including two or more circuit regions. In another illustrative embodiment, at least some of the two or more computational nodes further include one or more first stacks, each of the one or more first stacks including one or more electrical components on one or more layers, and each of the one or more first stacks electrically connected to at least one of the two or more circuit regions on the host substrate. In another illustrative embodiment, at least some of the two or more computational nodes further include one or more second stacks providing electrical connections between the two or more circuit regions, the one or more second stacks further providing electrical power to the two or more circuit regions. In another illustrative embodiment, at least some of the second stacks include an insulator wafer bonded to a die, the die further bonded to at least one of the two or more circuit regions. In another illustrative embodiment, at least one of the one or more second stacks includes a first electrical pathway to provide the electrical power to at least one of the two or more circuit regions, the first electrical pathway including an electrically-conductive via through the insulator wafer and at least one of an electrically-conductive via through the die or a capacitor in the die. In another illustrative embodiment, the die of at least one of the one or more second stacks includes one or more second electrical pathways to provide electrical connections between at least two of the two or more circuit regions. In another illustrative embodiment, the device further includes one or more additional second stacks providing electrical connections between the two or more computational nodes, at least some of the one or more additional second stacks including an additional insulator wafer bonded to an additional die, where the additional die provides electrical connections between selected circuit regions of at least two of the two or more computational nodes.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a conceptual side view of a macrochip with a host substrate formed as a reconstituted wafer, in accordance with one or more embodiments of the present disclosure.

FIG. 1B is a conceptual side view of a macrochip with a host substrate formed as a monolithic wafer, in accordance with one or more embodiments of the present disclosure.

FIG. 1C is a conceptual side view of a macrochip with a printed circuit board (PCB) in a secondary plane, in accordance with one or more embodiments of the present disclosure.

FIG. 1D is a conceptual side view of a macrochip with a chip-last interposer in a secondary plane, in accordance with one or more embodiments of the present disclosure.

FIG. 2 is a conceptual side view of a macrochip with an insulator wafer with electrically-conducting vias (IWV) directly connected to the host substrate, in accordance with one or more embodiments of the present disclosure.

FIG. 3A is a flow diagram illustrating steps performed in a method for manufacturing a macrochip, in accordance with one or more embodiments of the present disclosure.

FIG. 3B is a flow diagram illustrating sub-steps associated with the step of fabricating the host substrate formed as a reconstituted wafer, in accordance with one or more embodiments of the present disclosure.

FIG. 4 is a sequence of side-view panels depicting the flow diagram of FIG. 3B, in accordance with one or more embodiments of the present disclosure.

FIG. 5 is a conceptual side view of connecting component stacks and interconnect stacks to a host substrate using stack-to-wafer processing to form a macrochip, in accordance with one or more embodiments of the present disclosure.

FIG. 6 includes a top view of a macrochip formed as a computational node and insets with cross-section views, in accordance with one or more embodiments of the present disclosure.

FIG. 7A is a conceptual side view of a macrochip with buffer circuits without active transport integrated into high-bandwidth memory (HBM) component stacks, in accordance with one or more embodiments of the present disclosure.

FIG. 7B is a conceptual side view of a macrochip with buffer circuits with active transport integrated into HBM component stacks, in accordance with one or more embodiments of the present disclosure.

FIG. 7C is a conceptual side view of a macrochip in which buffer circuits with active transport are provided as circuit regions on host dies, in accordance with one or more embodiments of the present disclosure.

FIG. 7D is a conceptual side view of a macrochip in which buffer functionality for connectivity to an HBM component stack is directly integrated into frame circuit regions.

FIG. 7E is a conceptual side view of a macrochip configured as a computational node including buffer circuits as host dies situated between HBM component stacks, in accordance with one or more embodiments of the present disclosure FIG. 8A is a first sequence of side-view panels depicting fabrication of a first portion the macrochip illustrated in FIG. 7E, in accordance with one or more embodiments of the present disclosure.

FIG. 8B is a second sequence of side-view panels depicting fabrication of the macrochip illustrated in FIG. 7E, in accordance with one or more embodiments of the present disclosure.

FIG. 8C is a third sequence of side-view panels depicting fabrication of the macrochip illustrated in FIG. 7E, in accordance with one or more embodiments of the present disclosure.

FIG. 9A is a top view of a macrochip formed from multiple computational nodes as illustrated in FIG. 6, in accordance with one or more embodiments of the present disclosure.

FIG. 9B includes a section of FIG. 9A at increased magnification to illustrate the I/O modules in greater detail, in accordance with one or more embodiments of the present disclosure.

FIG. 10 is a top view of a portion of a macrochip and an inset corresponding to a cut-line illustrating an I/O module with an electronic integrated circuit (EIC) integrated into an interconnect die of an interconnect stack, in accordance with one or more embodiments of the present disclosure.

FIG. 11 is a top view of a portion of a macrochip and an inset corresponding to a cut-line illustrating an I/O module with an EIC provided as a host die, in accordance with one or more embodiments of the present disclosure.

FIG. 12 is a side view of a macrochip including two sub-macrochips on a common platen that are connected by a connector sub-macrochip including a frame circuit region and an interconnect stack to connect the sub-macrochips, in accordance with one or more embodiments of the present disclosure.

### DETAILED DESCRIPTION

Reference will now be made in detail to the subject matter disclosed, which is illustrated in the accompanying drawings. The present disclosure has been shown and described with respect to certain embodiments and specific features thereof. The embodiments set forth herein are illustrative rather than limiting. It should be readily apparent to those of ordinary skill in the art that various changes and modifications in form and detail may be made without departing from the spirit and scope of the disclosure.

Embodiments of the present disclosure are directed to systems and methods providing a macrochip (e.g., a device) including a host substrate having multiple circuit regions, where the macrochip further includes multiple stack structures (referred to herein as stacks) bonded or otherwise connected to the multiple circuit regions. In this way, the macrochip may provide an electrical device that spans the multiple circuit regions and the various stacks.

The term host substrate is used herein to refer to any component or combination of components that include circuit regions suitable for connection to form a macrochip. For example, a host substrate may include a monolithic substrate in which various circuit regions are formed on a common plane of the monolithic substrate. As another example, a host substrate may include a reconstituted wafer substrate including multiple dies or other components connected to a carrier substrate (e.g., a carrier wafer), where the multiple dies include the circuit regions to be connected to form a macrochip. Further, the various circuit regions on the various dies may be fabricated to be on a common plane once attached to the carrier substrate to facilitate bonding to various stacks.

The circuit regions on the host material may include any combination of active or passive electrical elements known in the art including, but not limited to, electrical traces, resistors, capacitors, transistors, amplifiers, or logic circuitry (e.g., computational circuitry). Further, the circuit regions may be fabricated using any technique known in the art. In some embodiments, the circuit regions are fabricated as one or more patterned layers using lithographic processing techniques. As an illustration, a patterned layer may be formed by deposition of a photoresist, exposing the photoresist with a pattern, etching the photoresist and one or more layers of underlying material to form a patterned structure. In this way, single or multi-layer circuit regions may be formed based on one or more patterned layers.

The term stack is used herein to refer to a structure designed to be connected to the host substrate (e.g., electrically and/or mechanically) as a single unit. In this way, a macrochip may be manufactured by separately fabricating the host substrate and multiple stacks and then connecting the stacks to the host substrate. In this way, each stack may be formed from potentially different materials and may potentially be fabricated by different fabrication techniques, yet still be integrated into a common device.

A stack may generally include one or more material layers or components. Further, it is contemplated herein that a macrochip may include multiple types of stacks. For example, a component stack may include any type of electrical component suitable for integration into the macrochip such as, but not limited to, active or passive circuit components, electrical traces, or vias. Further, the components in a component stack may be, but are not required to be, provided as additional circuit regions.

In some embodiments, a stack includes additional components (e.g., electrical components) located on one or more layers of a suitable substrate such as, but not limited to, one or more dies, one or more wafers, or the like. Such a stack is referred to herein as a component stack. The components of a component stack may be provided on any number of layers or substrates. For example, components of a component stack may be provided on one or more layers of a die, a wafer, or other suitable substrate. In some embodiments, a component stack includes two or more singluated dies (or other suitable substrates including, but not limited to, whole wafers or portions of wafers) stacked in a vertical direction with respect to constituent substrate planes, where any of the singulated dies may include electrical components connected through vertical integration. In this way, a component stack may be, but is not required to be, formed as a three-dimensional (3D) or vertically-integrated device using any technique known in the art. As an illustration, a component stack may include a stacked memory device such as, but not limited to, static random-access memory (SRAM) or dynamic RAM (DRAM). For instance, a component stack may include high-bandwidth-memory (HBM) elements implemented as multiple layers of DRAM vertically connected by vias (e.g., through-silicon vias (TSVs), or the like).

In some embodiments, a stack includes an insulator wafer (e.g., a wafer of an insulating material) bonded or otherwise connected to a die including one or more semiconductor layers (referred to herein as an interconnect die). Such as stack is referred to herein as an interconnect stack. Further, the term interconnect die is used herein to refer to any combination of one or more semiconductor layers bonded to the insulating wafer of an interconnect stack, where any of the one or more semiconductor layers may include active or passive features such as, but not limited to, electrical traces, vias, or signal repeaters. In some embodiments, an insulator wafer and the interconnect die of an interconnect stack include one or more vias suitable for delivering power to circuit regions of the host substrate. Accordingly, an interconnect die of an interconnect stack may provide electrical connections between any circuit regions on a host substrate and/or power delivery to any of the circuit regions on the host substrate.

More particularly, the insulator wafer of an interconnect stack may be formed using any insulating material such as, but not limited to, glass. Additionally, an insulator wafer including one or more electrically-conducting vias is referred to herein as an insulator wafer with vias or IWV. For example, the insulator wafer may be formed with glass having through-glass vias (TGVs) to facilitate power transfer through the insulating wafer. The interconnect die of an interconnect stack may further be formed from any number of layers of semiconductor material. Further, the interconnect die may include any combination of passive or active electrical elements for routing signals between the circuit regions on the host substrate and/or power distribution elements for power delivery to the host substrate such as, but not limited to electrical pathways (e.g., electrical traces), electrically-conductive vias, or deep trench capacitors (DTCs). For example, an interconnect die in an interconnect stack may be formed as one or more silicon layers with active or passive routing layers along with TGVs and DTCs for power delivery.

A macrochip may further include a wide variety of additional stacks or stack types. For example, a macrochip may include a stack formed as an IWV without an interconnect die to provide power delivery to one or more circuit regions of the host substrate but not interconnections between circuit regions. As another example, a macrochip may include dummy stacks that provide a mechanical rather an electrical function. For instance, it may be desirable to provide a macrochip in which the various stacks have a common height once attached to the host substrate. In this way, additional components such as, but not limited to, printed circuit boards (PCBs) or interposers may be disposed on top of the various stacks. In this configuration, one or more dummy stacks also having the common height may provide a consistent plane.

In a general sense, a macrochip may include any number of stacks of any type connected to the host substrate. For example, a macrochip may include a host substrate, one or more first stacks (e.g., stacks of a first type), one or more second stacks (e.g., stacks of a second type), and so on.

In some embodiments, a macrochip includes a host substrate with multiple circuit regions, one or more component stacks connected to any of the circuit regions, and one or more interconnect stacks providing electrical connections between circuit regions and/or power to the circuit regions. In this way, an operational macrochip may be formed by the component stacks and the circuit regions connected by the interconnect stacks, where the interconnect stacks further provide power to the circuit regions to power the circuit regions and/or connected components such as the component stacks.

It is contemplated herein that such an architecture may enable fabrication of a diverse range of macrochips for a wide variety of applications including, but not limited to, high-performance computing, artificial intelligence/machine learning training systems, data centers, or the like.

In some embodiments, a macrochip is formed by bonding various stacks (e.g., component stacks, interconnect stacks, or the like) to the host substrate using stack-to-wafer processing techniques. For example, stack-to-wafer processing may be implemented by first creating the various stacks (e.g., stacks of singulated dies, insulator wafers, or the like) followed by connecting the stack structures to a host substrate as a single unit. It is contemplated herein that stack-to-wafer processing enables the fabrication of complex devices with a variety of different stacks such as, but not limited to, component stacks (e.g., providing memory or other functions), interconnect stacks, dummy stacks, or the like as disclosed herein. In particular, various stacks fabricated using different techniques or die sizes may be readily combined to form a macrochip.

In some embodiments, connections between the various elements are provided as direct copper bonds (e.g., copper-to-copper bonds, copper fusion bonds, hybrid copper bonds (HCBs), or the like). For example, direct copper bonds may provide any or all of the connections between the interconnect die and the IWV of an interconnect stack, connections between an interconnect stack and the host substrate material, connections between constituent dies in a component stack, or connections between a component stack and the host substrate. It is contemplated herein that forming a macrochip from component stacks and interconnect stacks bonded to a host substrate through direct copper bonds may enable efficient, high-speed connections between the various elements with a high manufacturing yield such that the resulting macrochip may be suitable for demanding high-performance computing applications. For example, it is contemplated herein that the use of direct copper bonds may provide increased connection bandwidth than alternative techniques such as, but not limited to, microbumps (e.g., solder microbumps) with or without additional interconnect die layers.

The individual stack elements of a macrochip may be connected to the host substrate using any technique or combination of techniques known in the art including, but not limited to, direct copper bonds or microbumps.

In some embodiments, the interconnect stacks and the component stacks are fabricated to a common height to enable additional circuit elements in a secondary plane across faces of the interconnect stacks and/or component stacks opposite the host substrate. For example, additional circuit elements such as, but not limited to, one or more PCBs or one or more chip-last interposers may be fabricated in the secondary plane to provide additional functionality such as, but not limited to, power distribution or connectivity to additional components or systems. It is contemplated that a macrochip formed with multiple PCBs or chip-last interposers across interconnect stacks and component stacks may reduce an accumulation of mechanical stress due to thermal expansion across the macrochip relative to a device including a single PCB or chip-last interposer, which may enable a commensurate increase in the mechanical size of the macrochip. In some embodiments, systems and methods disclosed herein enable the manufacturing of macrochips limited only by the size of the wafer or panel used as the host substrate.

In some embodiments, the component stacks and interconnect stacks substantially cover a surface of the host substrate to provide a mechanically stable macrochip. Further, dummy stacks with the same height but no electrical functionality may be bonded to the host substrate as necessary in areas not covered by interconnect stacks or component stacks to facilitate a mechanically stable macrochip.

In some embodiments, a macrochip may include one or more insulator wafers with vias (IWVs) to provide a direct electrical connection between the host substrate and additional components such as, but not limited to, input-output (I/O) devices. In this configuration, such an IWV may have similar physical dimensions as an interconnect stack, but may be formed without the interconnect die. An IWV without an interconnect die may thus avoid the capacitance added by an interconnect die and may facilitate higher-bandwidth signal transfer than provided by an interconnect stack as disclosed herein.

Additional embodiments of the present disclosure are directed to a computing system formed as a macrochip. For example, a computing system may be formed as one or more computational nodes, where at least some of the computational nodes include computational logic connected to stacked memory (e.g., as component stacks). In this configuration, each computational node (or at least some of the computational nodes) may be formed as a macrochip based on the systems and methods disclosed herein. Further, multiple computational nodes may be connected using the systems and methods disclosed herein to form a larger macrochip.

Additional embodiments of the present disclosure are directed to methods for manufacturing macrochips.

In some embodiments, a macrochip is formed as a tiered structure. Macrochips formed as tiered structures are generally described in U.S. Pat. No. 8,536,693 issued on Sep. 19, 2012, which is incorporated herein by reference in its entirety. However, the present disclosure is not limited to tiered configurations as illustrated in the references above. For example, in some embodiments, a macrochip includes one or more tiered elements and one or more elements that span multiple tiers.

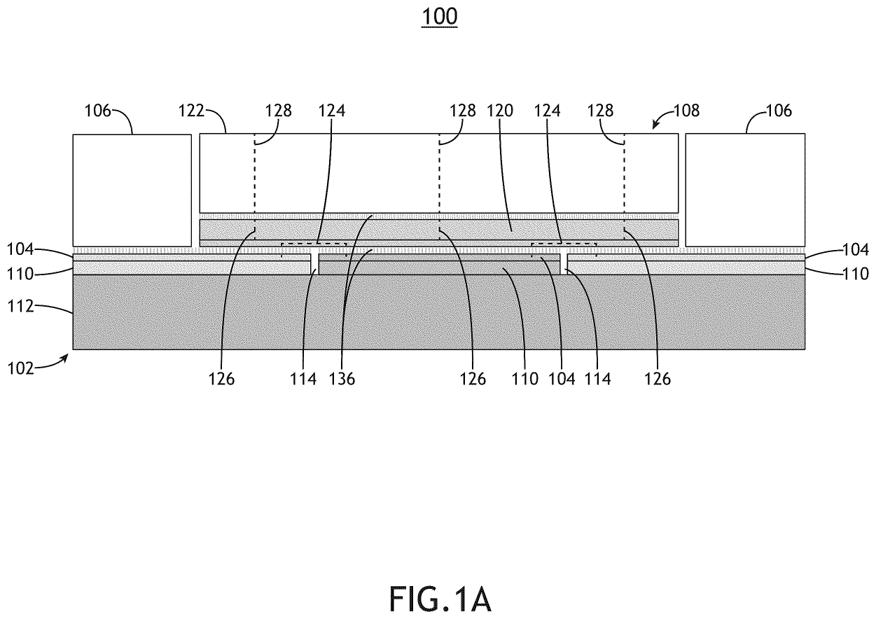

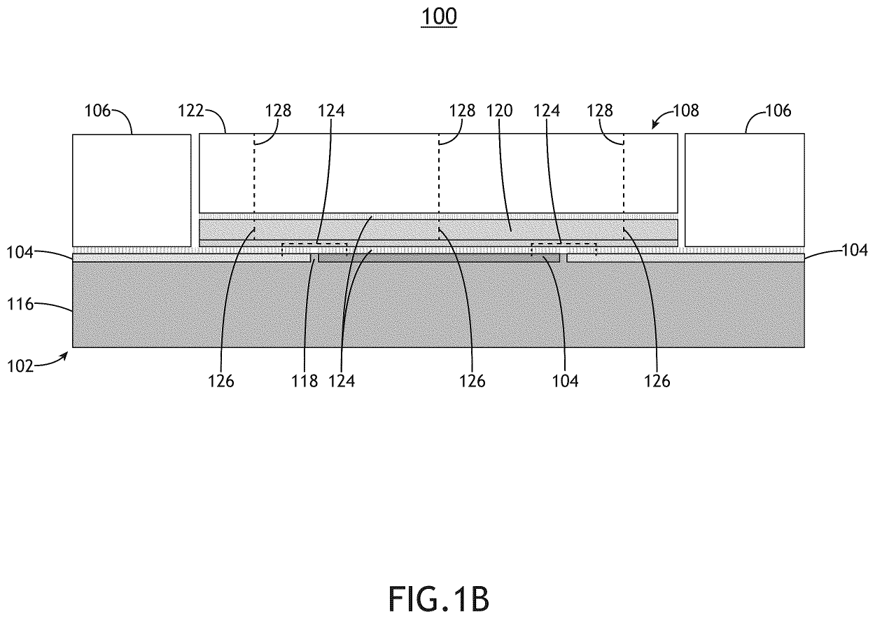

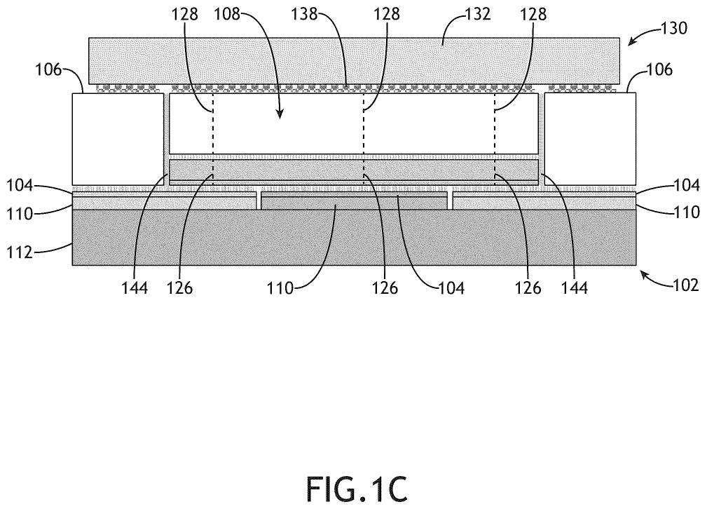

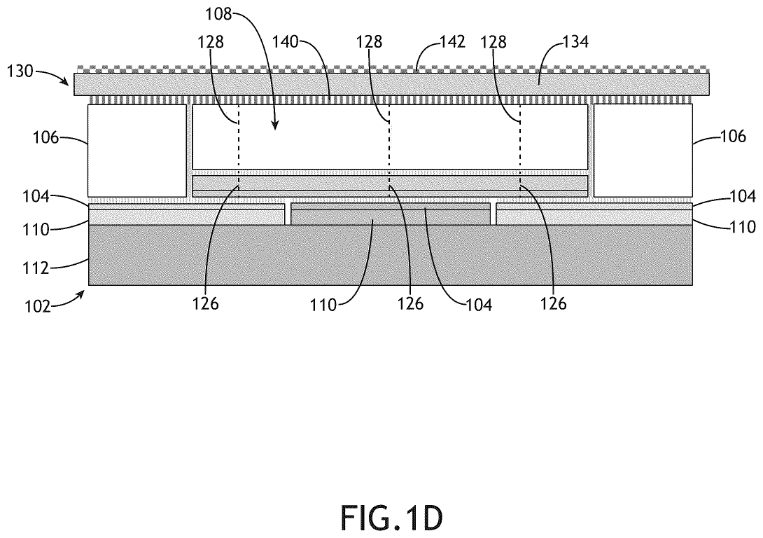

Referring now to FIGS. 1-12, systems and methods providing macrochips are described in greater detail, in accordance with one or more embodiments of the present disclosure.

In some embodiments, a macrochip 100 (e.g., a macrochip device) includes a host substrate 102 having multiple circuit regions 104, at least one component stack 106, and at least one interconnect stack 108. An interconnect stack 108 may provide power to any of the circuit regions 104 and/or connectivity between any of the circuit regions 104 or connected components such as one or more component stacks 106. In some embodiments, a particular interconnect stack 108 both provides power to one or more circuit regions 104 and connectivity between one or more circuit regions 104, which may be the same or different than the ones receiving the power. In some embodiments, a particular interconnect stack 108 provides either power to one or more circuit regions 104 or connectivity between one or more circuit regions 104. In this way, a macrochip 100 may generally include any combination of interconnect stacks 108 to facilitate both power delivery to and electrical connections between the circuit regions 104 on the host substrate 102.

The host substrate 102 may include any number or arrangement of circuit regions 104. In this way, the architecture disclosed herein may enable the fabrication of super-reticle macrochips using a wide range of techniques. FIG. 1A is a conceptual side view of a macrochip 100 with a host substrate 102 formed as a reconstituted wafer, in accordance with one or more embodiments of the present disclosure. FIG. 1B is a conceptual side view of a macrochip 100 with a host substrate 102 formed as a monolithic wafer, in accordance with one or more embodiments of the present disclosure. However, it is to be understood that FIGS. 1A and 1B, along with the associated descriptions are provided solely for illustrative purposes and are not limiting on the present disclosure.

In some embodiments, as illustrated in FIG. 1A, the host substrate 102 is formed as a reconstituted wafer. For example, FIG. 1A illustrates a host substrate 102 with three host dies 110 bonded or otherwise mounted to a carrier wafer 112 with circuit regions 104 exposed for connection to component stacks 106 and/or interconnect stacks 108. In this configuration, at least some of the interconnect stacks 108 may span any gaps 114 between the host dies 110 with the circuit regions 104 to provide connectivity between the circuit regions 104. Further, any of the component stacks 106 may be placed on a single host die 110 or span multiple host dies 110. It is contemplated herein that a macrochip 100 with interconnect stacks 108 connecting circuit regions 104 on different host dies 110 on a reconstituted host substrate 102 may provide a higher yield and lower complexity than typical macrochip manufacturing techniques using reconstituted wafers such as, but not limited to fan-out (FO) techniques, which may not readily accommodate integration with component stacks 106.

In some embodiments, as illustrated in FIG. 1B, the host substrate 102 is formed as a monolithic substrate 116 (e.g., a monolithic semiconductor wafer) having multiple circuit regions 104. For example, the various circuit regions 104 may be associated with different reticle exposures on the monolithic substrate 116 (e.g., different reticle exposure fields). In this configuration, at least some of the interconnect stacks 108 may span the gaps 118 between reticle exposure fields (e.g., reticle field streets) to provide electrical connections between the different reticle exposures to form an operational device that may be larger than any particular reticle field size. It is contemplated herein that a macrochip 100 including interconnect stacks 108 to connect circuit regions 104 from different reticle fields may provide a higher yield and lower complexity than typical super-reticle circuit manufacturing techniques such as, but not limited to, wafer-scale integration (WSI) using reticle stitching techniques to connect different reticle fields. In particular, WSI may suffer from defects due to the complexity of accurate reticle alignment, whereas interconnect stacks 108 as disclosed herein may be manufactured with high yield and provide high alignment accuracy. It is noted, however, that interconnect stacks 108 as disclosed herein may be used in combination with WSI reticle stitching techniques. For example, reticle stitching techniques may provide connections between at least some circuit regions 104 and interconnect stacks 108 may provide power to these circuit regions 104.

In some embodiments, typical super-reticle manufacturing techniques such as, but not limited to, WSI may further be used to extend the sizes of an interconnect stack 108 and/or a component stack 106 beyond a typical reticle field. In this way, the macrochip 100 may itself include super-reticle-sized components.

Referring generally to FIGS. 1A and 1B, a circuit region 104 on a host substrate 102 may include any combination of active or passive circuit elements suitable for integration with other components using an interconnect stack 108 as disclosed herein. Further, a macrochip 100 may include circuit regions 104 providing various functions that contribute to the operation of the macrochip 100. For example, circuit regions 104 may include, but are not limited to logic circuitry (e.g., to provide computational functions), routing circuitry, I/O circuitry, or memory. Further, any particular circuit region 104 may have a single type of circuitry or may combine multiple types of circuitry. In some embodiments, a macrochip 100 having a reconstituted die host substrate 102 may include host dies 110 with circuit regions 104 formed using different manufacturing techniques or nodes. In this way, the various circuit regions 104 may be tailored based on considerations such as, but not limited to, cost, complexity, or yield.

A component stack 106 may include any number or types of components suitable for integration into the macrochip 100. Further, a component stack 106 may be formed as one or more single-layer circuit regions or one or more multi-layer circuit regions (e.g., as a vertically-integrated component). Further, a macrochip 100 may include any number of component stacks 106 of the same or different design. For example, a component stack 106 may be formed as a stacked memory device such as, but not limited to, SRAM, DRAM, or an HBM. As another example, a component stack 106 may include passive or active electrical elements.

A component stack 106 may include any number of internal substrates or patterned layers. In some embodiments, a component stack 106 is formed as multiple dies of the same or different design that have been singulated and stacked (e.g., bonded) to form a single stacked structure that may subsequently be bonded to the host substrate 102. As another example, a component stack 106 may include a multilayer structure on a single internal substrate. Further, a component stack 106 may include any type or combination of internal substrates including, but not limited to, semiconductor substrates (e.g., silicon substrates) or glass substrates. A component stack 106 may additionally include various electrically-conducting vias (e.g., TSVs, TGVs, or the like) or other interconnects between constituent components to facilitate operation when connected to the host substrate 102 as part of the macrochip 100.

An interconnect stack 108 may include an interconnect die 120 bonded to an IWV 122 to form a stack structure that may in turn be bonded to the host substrate 102. In some embodiments, the interconnect die 120 is bonded to the IWV 122 by direct copper bonding.

The interconnect die 120 may include a die formed from any number of layers of suitable materials including, but not limited to, semiconductors (e.g., silicon, or the like). For example, an interconnect die 120 may include one or more patterned semiconductor layers (e.g., layers having structures formed through lithographic techniques) providing any combination of passive or active electrical elements suitable for providing electrical connections 124 between various components of the macrochip 100 including, but not limited to, circuit regions 104, components within any particular circuit region 104, or component stacks 106. For example, passive electrical elements may not require connection to a power source for operation and may include, but are not limited to, conductive paths (e.g., traces), conductive vias, capacitors (e.g., deep trench capacitors or DTCs), resistors, or inductors for power connections between the host substrate and a power plane. As another example, active elements may require connection to a power source and may include, but are not limited to, amplifiers or repeaters to facilitate buffered routing over longer distances or other functions. In some embodiments, an interconnect die 120 includes only passive electrical elements. It is contemplated herein that an interconnect die 120 including only passive electrical elements may often be fabricated with a higher yield than an interconnect die 120 with active elements. However, some applications may require or benefit from active elements in the interconnect die 120.

The interconnect die 120 may further include one or more power distribution elements to facilitate the distribution of power to any of the circuit regions 104 on the host substrate 102. For example, the interconnect die 120 may include, but is not limited to, electrically-conductive vias 126 (e.g., TSVs, or the like) or capacitors (e.g., DTCs, or the like). In this way, the interconnect die 120 may provide decoupling of the host substrate 102 from power supply noise and/or conditioning of power signals to the host substrate 102.

The IWV 122 of an interconnect stack 108 may be formed from any suitable insulating material such as, but not limited to, glass. The IWV 122 may further include one or more electrically-conductive vias 128 (e.g., TGVs). In this way, the combination of the IWV 122 and the interconnect die 120 may provide one or more electrical pathways for power distribution to the host substrate 102 through the respective vias. The power may be provided through any suitable source or distribution network. For example, as will be described in greater detail below, the power may be provided through a PCB, chip-last interposer, or the like located on an opposite face of the IWV 122 than the interconnect die 120.

It is contemplated herein that an interconnect stack 108 formed from an interconnect die 120 and an IWV 122 may provide various benefits for a macrochip 100. For example, the yields of both the interconnect die 120 and the IWV 122 may be relatively high, particularly for silicon interconnect dies with TSVs and TGV wafers. Additionally, production methods are readily available for fabrication of copper-filed TGV glass engineered to be thermal expansion matched to silicon, which may enable high performance under demanding applications in which substantive amounts of heat are generated during operation of the macrochip 100. In this way, the use of an interconnect stack 108 may provide a robust, reliable, and cost-effective technique for macrochip fabrication. As another example, the use of an IWV 122 formed from an insulator may obviate the need to manufacture an insulating liner around the TGV copper, which may be necessary in the case of alternative materials. Additionally, as will be described in greater detail below, an IWV 122 without an interconnect die 120 may provide high-performance routing of serialized high-speed signals, which may be useful for I/O routing to and from the macrochip 100. Accordingly, the systems and methods disclosed herein provide a flexible architecture for macrochip fabrication.

Referring now to FIGS. 1C and 1D, a macrochip 100 may further include one or more circuit elements in a secondary plane 130 located on an opposite side of the interconnect stacks 108 and/or component stacks 106 as the host substrate 102. A macrochip 100 may generally include any number or type of components in a secondary plane 130 such as, but not limited to, one or more PCBs or one or more interposers (e.g., chip-last interposers, or the like). FIG. 1C is a conceptual side view of a macrochip 100 with a PCB 132 in a secondary plane 130, in accordance with one or more embodiments of the present disclosure. FIG. 1D is a conceptual side view of a macrochip 100 with a chip-last interposer 134 in a secondary plane 130, in accordance with one or more embodiments of the present disclosure.

In some embodiments, an interconnect stack 108 additionally provides electrical connectivity between the circuit regions 104 in the plane of the host substrate 102 to components in the secondary plane 130. For example, the secondary plane 130 may include circuitry (e.g., power distribution circuitry, power distribution components, or the like) such as, but not limited to, one or more power sources, voltage converters or transformers. In this way, the secondary plane 130 may be a power plane. As an illustration, the secondary plane 130 may distribute power to the various electrical pathways in the interconnect stacks 108 (e.g., vias, or the like) for distribution down to the circuit regions 104 on the host substrate 102. In some embodiments, this power is then distributed to one or more component stacks 106 either directly through the circuit regions 104 or by further routing through an interconnect die 120. In some embodiments, one or more component stacks 106 are configured to receive power directly from components in the secondary plane 130.

Additionally, the components in the secondary plane 130 may facilitate connections of the macrochip 100 to additional components or systems. For example, as will be described in greater detail below, various I/O components located at least partially in the secondary plane may provide connectivity between the macrochip 100 and additional systems.

As illustrated in FIGS. 1C and 1D, the various components attached to the host substrate 102 (e.g., the interconnect stacks 108, the component stacks 106, or the like) may have a common height with respect to the host substrate 102, which may facilitate the fabrication of components such as a PCB 132 or a chip-last interposer 134 in a secondary plane 130. In some embodiments, the macrochip 100 further includes one or more dummy elements (e.g., fill die, dummy stacks, or the like) to at least partially cover portions of the host substrate 102 not covered by component stacks 106 or interconnect stacks 108 to provide increased contact area and mechanical stability for components in the secondary plane 130.

Referring now generally to FIGS. 1A-1D, the various components of the macrochip 100 may be connected using any technique known in the art including, but not limited to, direct copper bonds, microbumps (e.g., with redistribution layers (RDLs) as necessary), pillars, bond pad connections, or C4 bumps (e.g., controlled collapse chip connection bumps). In some embodiments, direct copper bonds 136 connect the components of the macrochip 100 including, but not limited to, the interconnect die 120 to the IWV 122, an interconnect stack 108 to the host substrate 102, an interconnect stack 108 to a component in the secondary plane 130, a component stack 106 to the host substrate 102, a component stack 106 to a component in the secondary plane 130, or internal connections in a component stack 106. It is contemplated herein that direct copper bonds may provide increased performance relative to microbumps such as, but not limited to, increased communication bandwidth or increased connection density. For example, solder microbumps may typically be manufactured with a pitch on the order of 40-50 micrometers (μm), whereas direct copper bonds may be manufactured with pitches on the order of 10 μm or smaller. In the case of a component stack 106 configured as stacked memory (e.g., a HBM), the use of direct copper bonds internal and/or external to the component stack 106 may enable increased interface widths relative to typical HBMs fabricated using microbump technology. As an illustration, conventional 1024 (1K) signals may increase by factors of 2, 4, 8, 16, 32, or more. Additionally, the increased bandwidth and/or connectivity provided by direct copper bonds may enable an increase of the stack height of the component stack 106 since the stack height may be limited at least in part by the connection bandwidth.

In some embodiments, different connection technologies are used to connect different components. For example, microbumps and possibly redistribution layers (RDLs) may be suitable for power connections or relatively low-bandwidth connections. As an illustration, FIG. 1C depicts the use of preformed bond pads on the interconnect stack 108 and component stacks 106 to connect to the PCB 132 using bumps 138 or pillars. As another illustration, FIG. 1D depicts the use of an RDL and microbumps 140 to connect the interconnect stack 108 and the component stacks 106 to the chip-last interposer 134 and C4 bumps 142 on an opposite side of the chip-last interposer 134 for connections to additional components. It is to be understood, however, that the illustrated connection techniques are provided solely for illustrative purposes and that any components of the macrochip 100 may be connected using any technique. Further, gaps between stack components (e.g., component stacks 106, interconnect stacks 108, dummy stacks, or the like) may be filled with a fill material 144. For example, the fill material 144 may be in insulating material to facilitate deposition of conductive material providing electrical connections between the interconnect stacks 108 and/or component stacks 106 to components in a secondary plane 130 without impacting the underlying structures. As another example, the fill material 144 may provide mechanical stability to the macrochip 100.

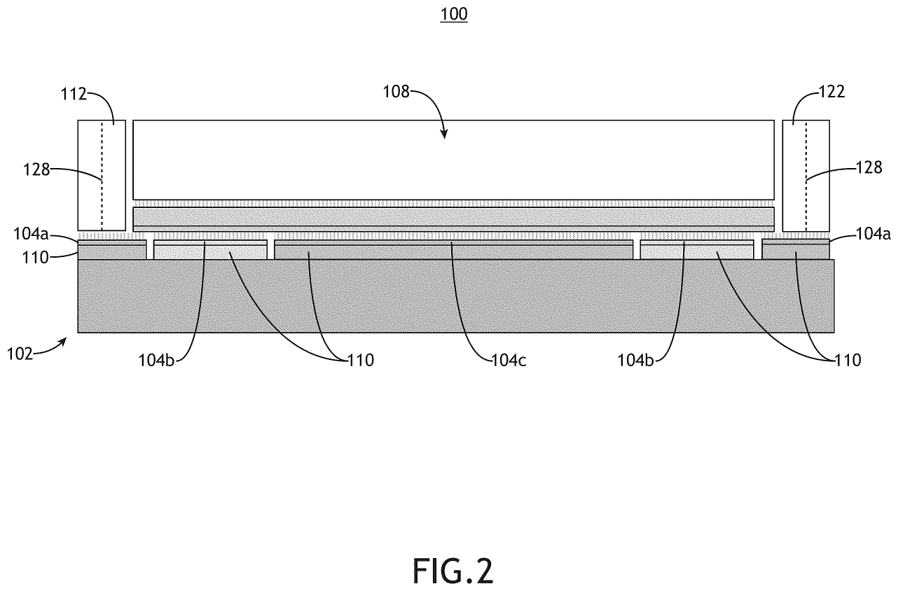

Referring now to FIG. 2, in some embodiments, the macrochip 100 includes at least one IWV 122 directly connected to at least one circuit region 104. FIG. 2 is a conceptual side view of a macrochip 100 with an IWV 122 directly connected to the host substrate 102, in accordance with one or more embodiments of the present disclosure.

An IWV 122 directly connected to a circuit region 104 of the host substrate 102 may be similar to an interconnect stack 108 without the interconnect die 120 portion. As illustrated in FIG. 2, such an IWV 122 may be connected to the host substrate 102 in a manner similar to an interconnect stack 108 (e.g., using direct copper bonds, or the like) and may further be designed to have a common height with any interconnect stacks 108 and/or component stacks 106 to provide a consistent secondary plane 130.

It is contemplated herein that an IWV 122 directly connected to a circuit region 104 may facilitate higher-bandwidth signal transfer than provided by an interconnect stack 108 with both an IWV 122 and an interconnect die 120 in part due to capacitance and other parasitic effects in the interconnect die 120. Accordingly, an IWV 122 directly connected to a circuit region 104 may be well suited for, but is not limited to, providing high-speed I/O communication to and/or from the macrochip 100. For example, FIG. 2 illustrates a macrochip 100 including IWVs 122 on exterior regions connected to circuit regions 104a configured as I/O die, which may be further connected to additional circuit regions 104b,c through an interconnect die 120 of an adjacent interconnect stack 108.

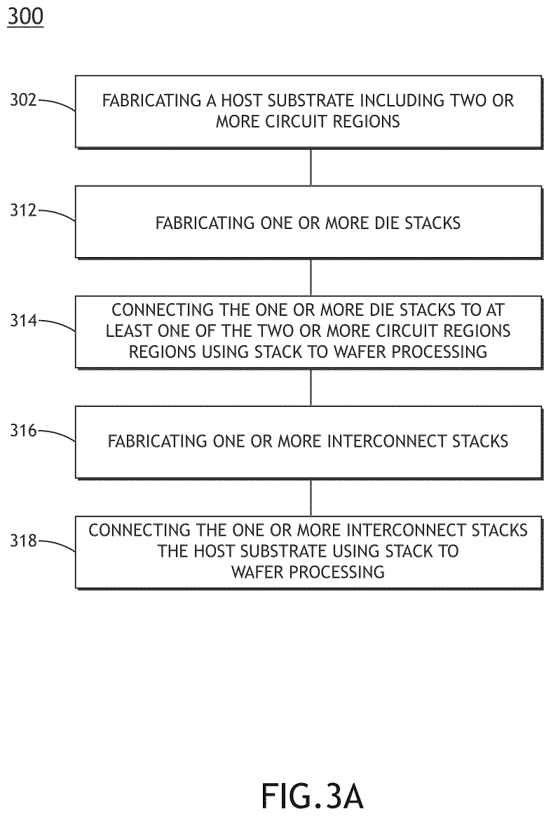

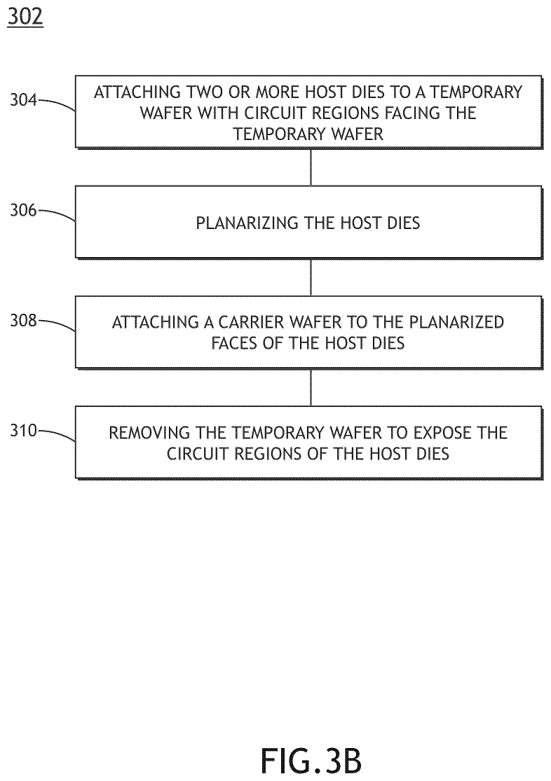

Referring now to FIGS. 3A-5, techniques for manufacturing a macrochip 100 are described in greater detail, in accordance with one or more embodiments of the present disclosure.

FIG. 3A is a flow diagram illustrating steps performed in a method 300 for manufacturing a macrochip 100, in accordance with one or more embodiments of the present disclosure. The embodiments and enabling technologies described previously herein in the context of the macrochip 100 as illustrated in FIGS. 1A-1D should be interpreted to extend to the method 300. It is further noted, however, that the method 300 is not limited to the architecture of the macrochip 100 illustrated in FIGS. 1A-1D. Further, it is to be understood that the method 300 is not limited to the number or order of steps illustrated in FIG. 3A or 3B. For example, the method 300 does not require all steps illustrated in FIG. 3A or 3B. As another example, the method 300 may include additional steps not explicitly illustrated in FIG. 3A or 3B. As a further example, any of the steps illustrated in FIG. 3A or 3B may be performed in any order.

In some embodiments, the method 300 includes a step 302 of fabricating a host substrate 102 including two or more circuit regions 104. For example, as described with respect to FIG. 1B, the host substrate 102 may include a monolithic wafer having multiple circuit regions 104 which may be, but are not required to be, associated with different reticle exposures. As another example, as described with respect to FIG. 1A, the host substrate 102 may include a reconstituted wafer with circuit regions 104 distributed between two or more host dies 110.

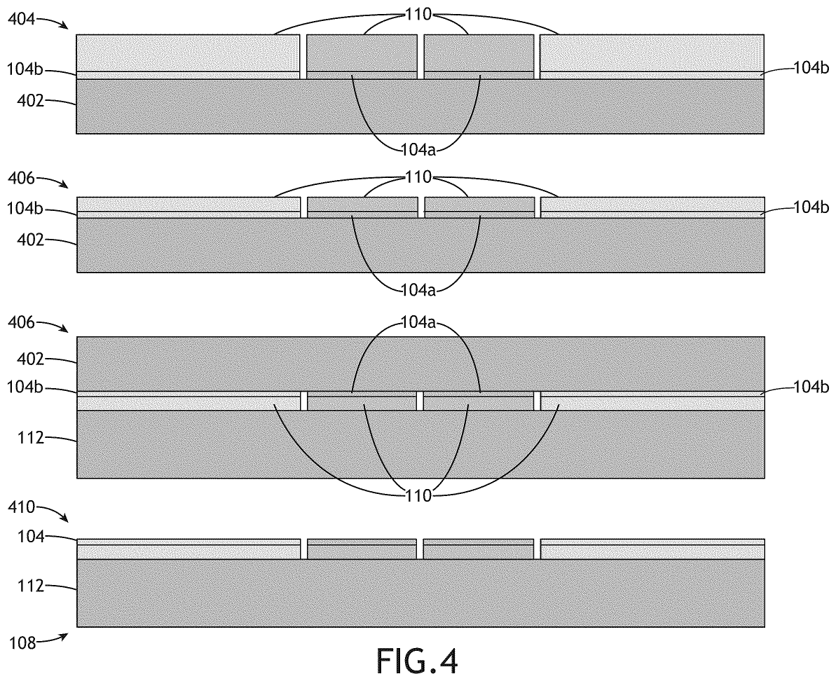

FIG. 3B is a flow diagram illustrating sub-steps associated with the step 302 of fabricating the host substrate 102 formed as a reconstituted wafer, in accordance with one or more embodiments of the present disclosure. FIG. 4 is a sequence of side-view panels depicting the flow diagram of FIG. 3B, in accordance with one or more embodiments of the present disclosure. It is to be understood that FIGS. 3B and 4 are provided solely for illustrative purposes and should not be interpreted as limiting.

In some embodiments, fabricating a reconstituted die host substrate 102 includes a step 304 of attaching two or more host dies 110 to a temporary wafer 402 with circuit regions 104 facing the temporary wafer 402, which is illustrated in panel 404 of FIG. 4. The host substrate 102 may any number or type of circuit regions 104 suitable for integration into a macrochip 100. FIG. 4 depicts a first type of circuit region 104a and a second type of circuit region 104b on the temporary wafer 402. For example, a host substrate 102 may include circuit regions 104 providing different functions such as, but not limited to, logic circuitry (e.g., computational logic), routing circuitry, I/O circuitry, or memory. As another example, a host substrate 102 may include circuit regions 104 fabricated using different manufacturing techniques or nodes. As an illustration, a circuit region 104 providing logic circuitry may be fabricated using a first manufacturing node or process providing high-density elements with relatively small feature sizes, whereas a circuit region 104 providing routing or I/O circuitry may be fabricated using a second manufacturing node or process providing relatively lower density elements with relatively larger feature sizes. In this way, different tradeoffs between performance, yield, cost, and the like may be made for different host dies 110.

In some embodiments, fabricating a reconstituted die host substrate 102 includes a step 306 of planarizing the host dies 110, which is illustrated in panel 406 of FIG. 4. In this way, the heights (or thicknesses) of the various host dies 110 may be made uniform. Further, the host dies 110 may be thinned to any selected height.

In some embodiments, fabricating a reconstituted die host substrate 102 includes a step 308 of attaching a carrier wafer 112 to the planarized faces of the host dies 110, which is illustrated in panel 408 of FIG. 4. In panel 408, the orientation is reversed relative to panel 406 such that the carrier wafer 112 is on the bottom of the figure. It is noted, however, that the orientations in FIG. 4 are purely illustrative.

In some embodiments, fabricating a reconstituted die host substrate 102 includes a step 310 of removing the temporary wafer 402 to expose the circuit regions 104 of the host dies 110, which is illustrated in panel 410 of FIG. 4.

Referring generally to FIGS. 3B and 4, FIGS. 3B and 4 depict a technique for providing co-planar circuit regions 104 on various host dies 110. However, it is to be understood that any technique for providing co-planar circuit regions 104 is within the spirit and scope of the present disclosure.

Referring again to FIG. 3A, in some embodiments, the method 300 includes a step 312 of fabricating one or more component stacks 106, where any particular component stack 106 may include any multilayer component suitable for integration into a macrochip 100. For example, a component stack 106 may include, but is not limited to, a stacked memory element or logic circuitry.

In some embodiments, the method 300 includes a step 314 of connecting the one or more component stacks 106 to at least one of the two or more circuit regions 104 using stack-to-wafer processing. In some embodiments, the method 300 includes a step 316 of fabricating one or more interconnect stacks 108, where at least some of the interconnect stacks 108 include an insulator wafer (with or without electrically-conductive vias 128) bonded to an interconnect die 120. In some embodiments, the method 300 includes a step 318 of connecting the one or more interconnect stacks 108 to the host substrate using stack-to-wafer processing.

The component stacks 106 and the interconnect stacks 108 may be connected to the circuit regions 104 of the host substrate 102 using any technique known in the art. In some embodiments, the component stacks 106 and/or the interconnect stacks 108 are connected to the circuit regions 104 of the host substrate 102 using direct copper bonding, which may facilitate high-density, high-bandwidth connections.

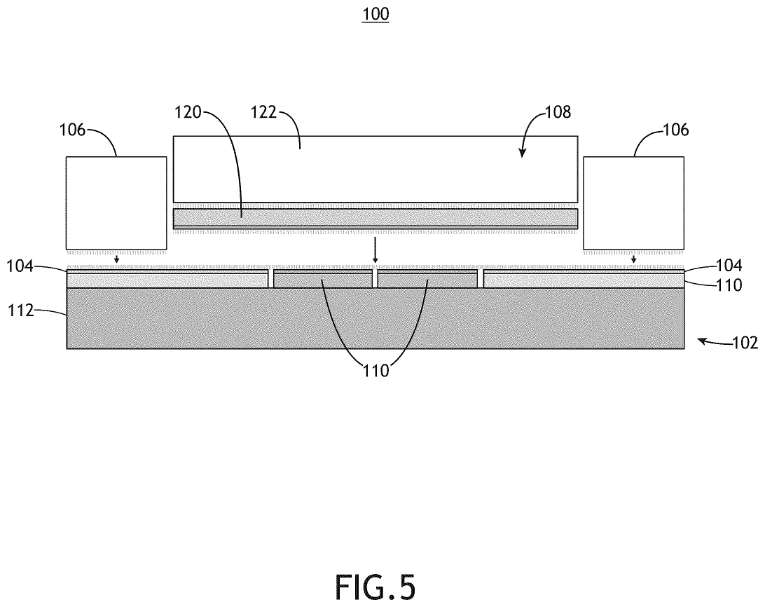

FIG. 5 is a conceptual side view of connecting component stacks 106 and interconnect stacks 108 to a host substrate 102 using stack-to-wafer processing to form a macrochip 100, in accordance with one or more embodiments of the present disclosure. In particular, FIG. 5 illustrates how the various component stacks 106 as well as an interconnect stack 108 are fabricated as individual stacked elements, each of which may be connected to the host substrate 102 as a stack. Further, it is noted that the host dies 110 and/or any interconnect stacks 108 may be connected to the host substrate 102 separately or in combination as part of any number of connection steps.

In some embodiments, the method 300 includes a step 320 of connecting one or more circuit components to a secondary plane 130 on faces of the component stacks 106 and/or interconnect stacks 108 such as, but not limited to, a PCB 132 or a chip-last interposer 134 as illustrated in FIGS. 1C and 1D, respectively.

Although not explicitly shown, it is contemplated herein that stack-to-wafer processing may be used to connect additional components to the host substrate 102 such as, but not limited to, IWVs 122 without interconnect dies 120 (e.g., as illustrated in FIG. 2) or dummy stacks (e.g., suitable for creating a stable and/or uniform secondary plane 130).

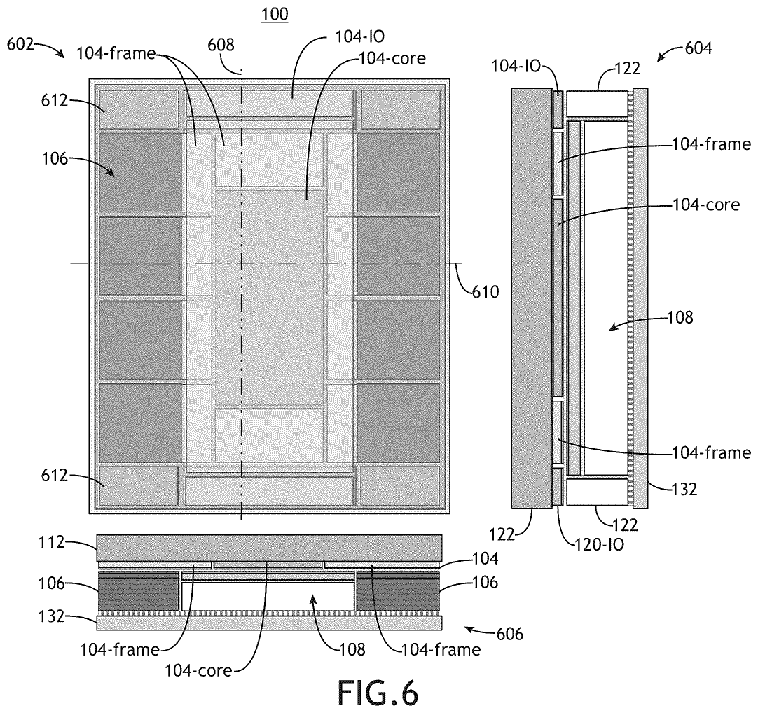

Referring now to FIGS. 6-12, various non-limiting examples of macrochips 100 are described, in accordance with one or more embodiments of the present disclosure. In particular, FIGS. 6-12 depict computational systems fabricated using one or more macrochips 100.

FIG. 6 includes a top view 602 of a macrochip 100 formed as a computational node and insets 604, 606 with cross-section views, in accordance with one or more embodiments of the present disclosure. In particular, the inset 604 depicts a cross-section view of the macrochip 100 along cut-line 608 and inset 606 depicts a cross-section view of the macrochip 100 along cut-line 610.

In some embodiments, a macrochip 100 configured as a computational node is formed from circuit regions 104 including computational logic circuitry surrounded by component stacks 106 including stacked memory (e.g., HBM, or the like), where various circuit regions 104 and memory component stacks 106 are connected by one or more interconnect stacks 108. The one or more interconnect stacks 108 may further provide power to at least the circuit regions 104 delivered through circuit elements in a secondary plane 130 (e.g., one or more PCBs 132, or the like). The circuit regions 104 may further include additional circuitry such as, but not limited to, routing circuitry to connect the memory component stacks 106 to the computational logic circuitry, or I/O circuitry to facilitate connections between the macrochip 100 and additional components. In some embodiments, a macrochip 100 configured as a computational node further includes one or more IWVs 122 to provide high-speed I/O to and from the macrochip 100 (e.g., as illustrated in FIG. 2).

A macrochip 100 configured as a computational node may have any number or type of circuit regions 104. For example, FIG. 6 illustrates a non-limiting configuration of a macrochip 100 including a core circuit region 104-core surrounded by frame circuit regions 104-frame and I/O circuit region 104-IO, where the memory component stacks 106 are mounted to the frame circuit regions 104-frame. In this configuration, the core circuit region 104-core may include computational logic circuitry and the frame circuit regions 104-frame may include routing and/or I/O circuitry. An interconnect stack 108 may overlap the core circuit region 104-core and the frame circuit regions 104-frame to provide electrical connections between the core circuit region 104-core and the memory component stacks 106 via the frame circuit regions 104-frame. The interconnect stack 108 may further provide power to any combination of the core circuit region 104-core, the frame circuit regions 104-frame, or the memory component stacks 106. For example, the inset 604 illustrates connectivity between the core circuit region 104-core, the frame circuit regions 104-frame, and the memory component stacks 106 via the interconnect die 120 of the interconnect stack 108. It is noted that the inset 604 is similar to FIGS. 1A and 1C such that the descriptions of FIGS. 1A and 1C extend to FIG. 6.

As described previously herein, a host substrate 102 with multiple types of circuit regions 104 (here, a core circuit region 104-core, frame circuit regions 104-frame, and I/O circuit region 104-IO) may enable tailoring of considerations such as, but not limited to, performance, yield, complexity, and cost for the various circuit regions 104. For example, the core circuit region 104-core may include high-performance computational logic on an advanced manufacturing node, whereas the frame circuit regions 104-frame and/or the I/O circuit region 104-IO may be fabricated using a more cost-effective manufacturing node that may also be more well-suited for routing and I/O functions.

FIG. 6 further illustrates a macrochip 100 with IWVs 122 connected to the I/O circuit region 104-IO to provide high-speed signal routing to and from the macrochip 100. For example, the inset 606 illustrates connectivity between the I/O circuit region 104-IO and frame circuit regions 104-frame (and thus any of the connected components of the macrochip 100) via the interconnect die 120 of the interconnect stack 108. It is noted that the inset 606 is similar to FIG. 2 such that the description of FIG. 2 extends to FIG. 6.

FIG. 6 further illustrates a PCB 132 in a secondary plane 130 connected to various components of the macrochip 100 including the interconnect stack 108, the component stacks 106, the IWVs 122 that are directly connected to the I/O circuit region 104-IO, and dummy dies 612. In this way, the PCB 132 can provide power for distribution to the host dies 110 (e.g., through the interconnect stack 108) and the memory component stacks 106 (e.g., either directly or through the interconnect stack 108). It is to be understood, however, that the PCB 132 is not limited to power distribution and may perform additional functions such as, but not limited to signal routing.

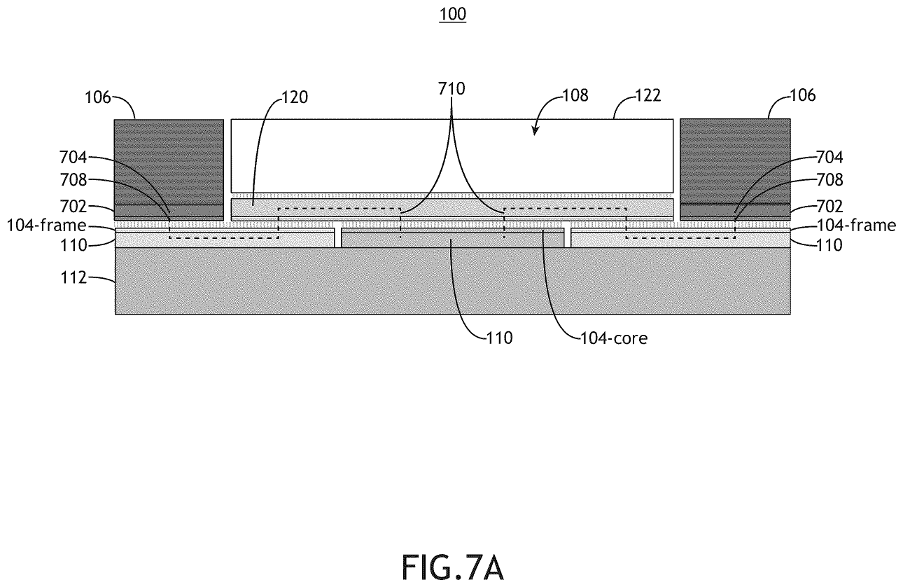

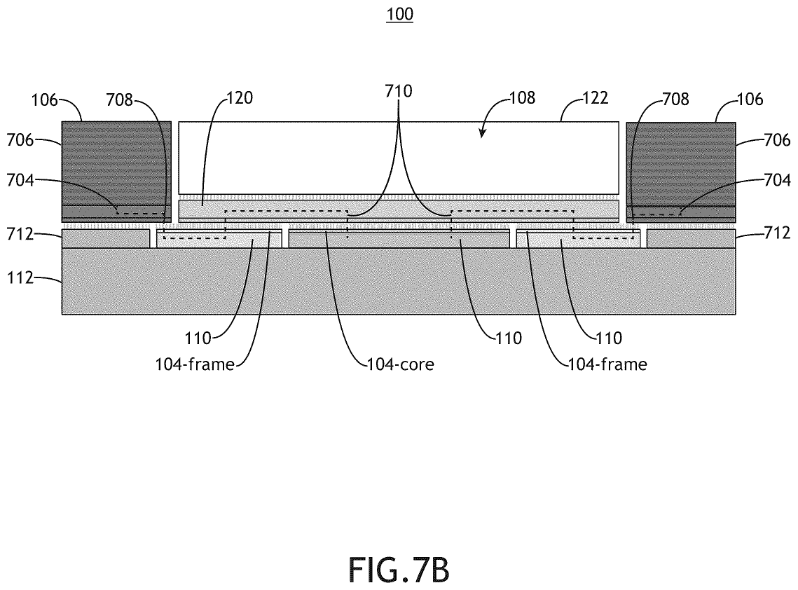

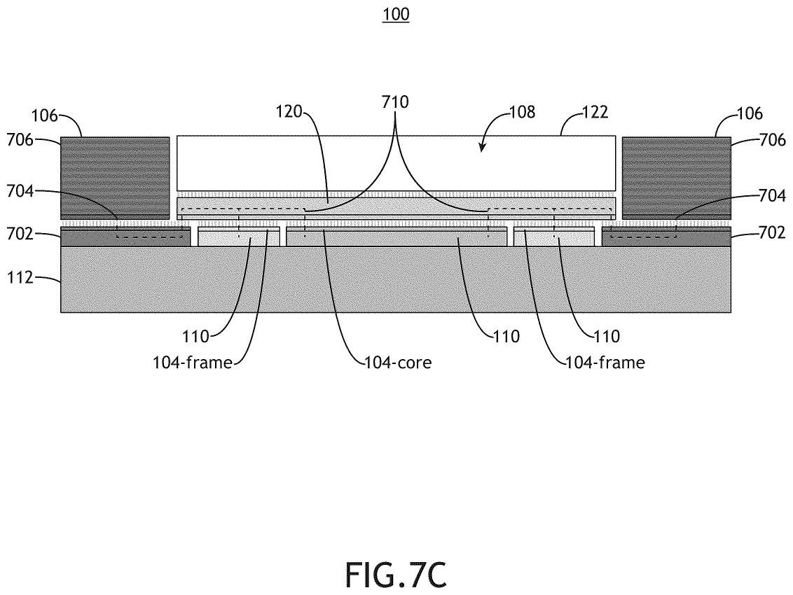

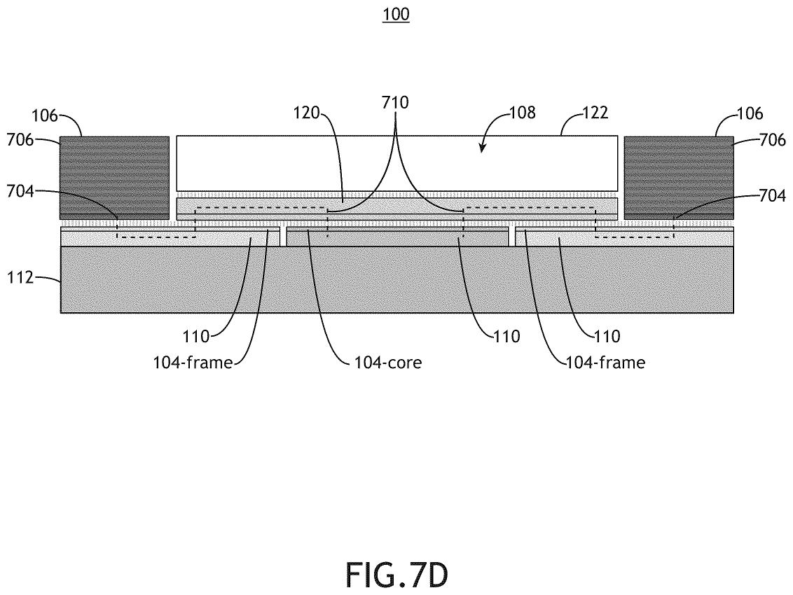

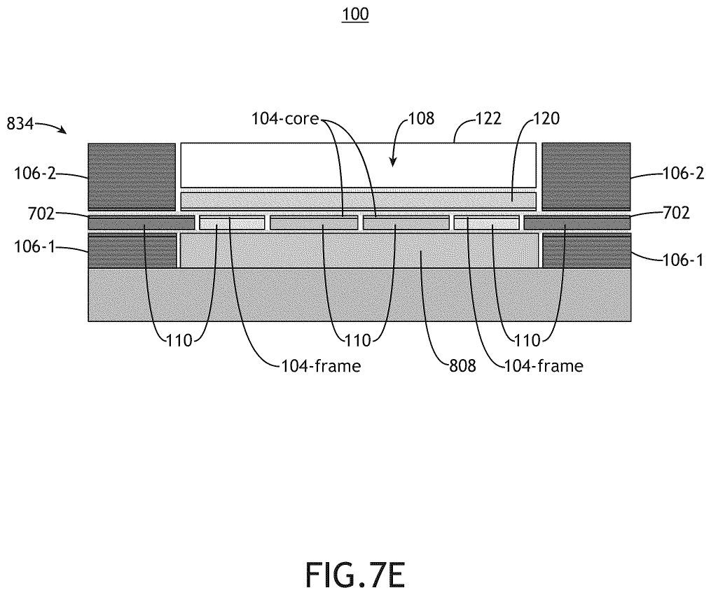

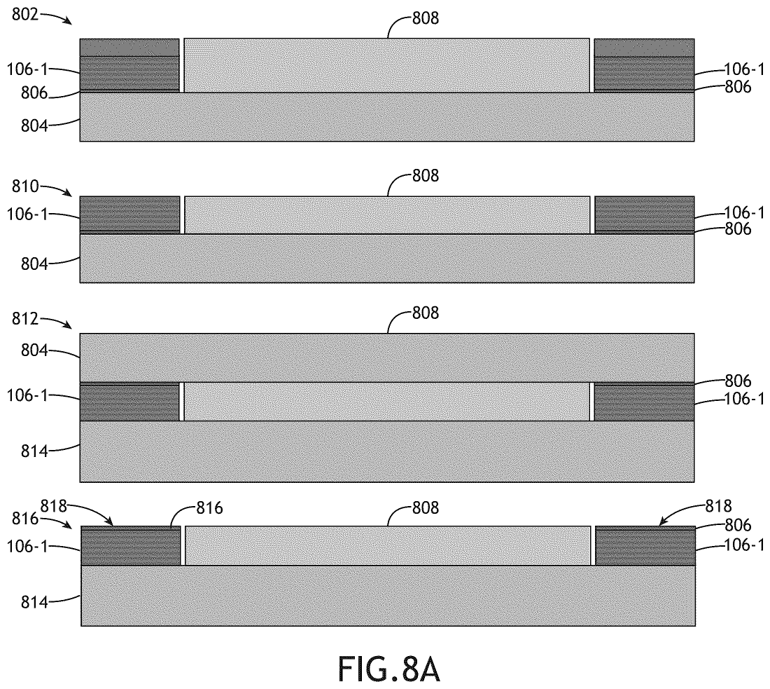

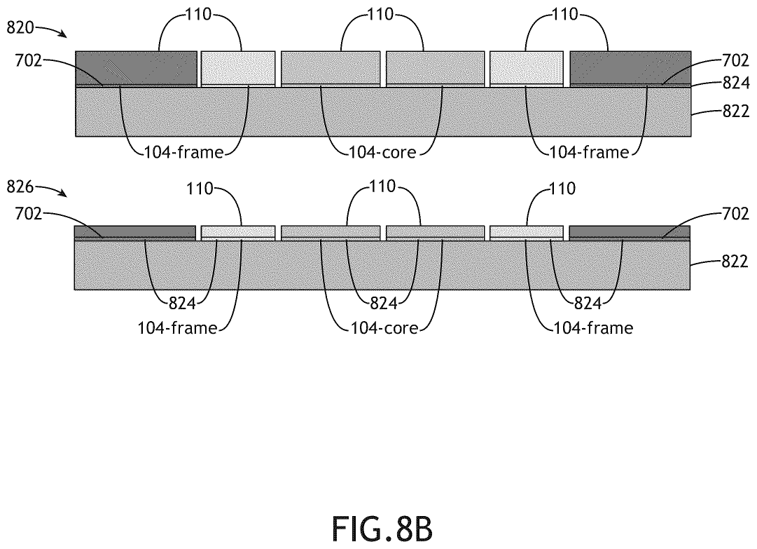

Referring now to FIGS. 7A-8B, it is contemplated herein that the systems and methods disclosed herein may be suitable for providing macrochips 100 with various memory architectures (e.g., various configurations of memory component stacks 106). In particular, FIGS. 7A-8B illustrate non-limiting variations of HBM component stacks 106 having different buffer and data transport (e.g., connectivity) configurations. In some embodiments, a macrochip 100 utilizes active transport such as parallel data transport across interconnect busses, which may be periodically buffered as needed by active repeater circuitry. In some embodiments, a macrochip 100 utilizes serialized data transmission, which may potentially be provided over relatively longer, sparser channels.

FIG. 7A is a conceptual side view of a macrochip 100 with buffer circuits 702 without active transport integrated into HBM component stacks 106, in accordance with one or more embodiments of the present disclosure. In some embodiments, an HBM component stack 106 includes an integrated buffer circuit 702 that is connected to a frame circuit region 104-frame (e.g., using a stack-to-wafer process as described with respect to FIGS. 3A and 3B). In this configuration, a connection between the HBM component stack 106 and the frame circuit region 104-frame may be at any location on the buffer circuit 702. For example, FIG. 7A illustrates a configuration of an HBM component stack 106 with a central memory stack connection point 704 between a memory stack 706 and a buffer circuit 702, along with a central buffer-to-frame connection point 708 between the buffer circuit 702 and the frame circuit region 104-frame. The frame circuit region 104-frame may then provide transport of signals to and from the HBM component stack 106 (e.g., active transport). As illustrated in FIG. 7A, the macrochip 100 may provide an electrical pathway 710 from the HBM component stack 106 to a core circuit region 104-core via the frame circuit region 104-frame and the interconnect die 120 of the interconnect stack 108.

FIG. 7B is a conceptual side view of a macrochip 100 with buffer circuits 702 with active transport integrated into HBM component stacks 106, in accordance with one or more embodiments of the present disclosure. In some embodiments, an HBM component stack 106 includes an integrated buffer circuit 702 as illustrated in FIG. 7A, but where the buffer circuit 702 provides a buffer-to-frame connection point 708 near an edge of the buffer circuit 702 (e.g., the buffer circuit 702 provides active signal transport). In this configuration, the size of the frame circuit region 104-frame may be reduced and partially replaced by a fill die 712, which may reduce cost and complexity.

FIG. 7C is a conceptual side view of a macrochip 100 in which buffer circuits 702 with active transport are provided as circuit regions 104 on host dies 110, in accordance with one or more embodiments of the present disclosure. For example, FIG. 7C illustrates an HBM component stack 106 without an integrated buffer circuit 702 having a central memory stack connection point 704 for connecting to a buffer circuit 702 located in the same plane as the other host dies 110. In this configuration, the interconnect die 120 of the interconnect stack 108 may overlap with the buffer circuit 702 to provide connectivity to additional host dies 110 such as the core circuit region 104-core and/or any frame circuit regions 104-frame.

FIG. 7D is a conceptual side view of a macrochip 100 in which buffer functionality for connectivity to an HBM component stack 106 is directly integrated into a frame circuit regions 104-frame. For example, FIG. 7D illustrates an HBM component stack 106 without an integrated buffer circuit 702 having a central memory stack connection point 704 connected directly to a frame circuit region 104-frame. In this way, the macrochip 100 may provide an electrical pathway 710 from the HBM component stack 106 (e.g., the memory stack 706) to a core circuit region 104-core via the frame circuit region 104-frame and the interconnect die 120 of the interconnect stack 108 without the need for an additional dedicated buffer circuit 702.

FIG. 7E is a conceptual side view of a macrochip 100 configured as a computational node including buffer circuits 702 as host dies 110 situated between HBM component stacks 106, in accordance with one or more embodiments of the present disclosure. In this way, the amount of memory accessible to a core circuit region 104-core providing computational logic may be increased without extending a lateral footprint of the macrochip 100. For example, the height of an HBM component stack 106 may be limited by speed and bandwidth requirements such that simply increasing the height of an HBM component stack 106 (e.g., a number of memory layers) may not be feasible within certain speed and/or bandwidth requirements. However, as illustrated in FIG. 7E, the systems and methods disclosed herein may enable multi-layer memory configurations. In particular, FIG. 7E illustrates electrical pathways 710 from multiple HBM component stacks 106 to a core circuit region 104-core through a single buffer circuit 702, which is configured here on a host die 110.

FIG. 8A is a first sequence of side-view panels depicting fabrication of a first portion the macrochip 100 illustrated in FIG. 7E, in accordance with one or more embodiments of the present disclosure. In panel 802, bottom-layer HBM component stacks 106-1 are mounted to a temporary carrier substrate 804 with active layers 806 proximate to the temporary carrier substrate 804. The HBM component stacks 106-1 may be mounted using any technique known in the art including, but not limited to, a stack-to-wafer process. A fill die 808 is further mounted to the temporary carrier substrate 804. In panel 810, backsides of the HBM component stacks 106-1 and the fill die 808 are planarized. In panel 812, a first carrier substrate 814 is mounted to the planarized backsides of the HBM component stacks 106-1 and the fill die 808. As a result, the HBM component stacks 106-1 and the fill die 808 may be co-planar with common thicknesses. It is noted that the vertical orientation of panel 812 is flipped with respect to panel 810. In panel 816, the temporary carrier substrate 804 is removed to expose the active layers 806 of the HBM component stacks 106-1. For illustration, the plane containing the active layers 806 of the HBM component stacks 106-1 is referred to as a carrier plane 818.

FIG. 8B is a second sequence of side-view panels depicting fabrication of the macrochip 100 illustrated in FIG. 7E, in accordance with one or more embodiments of the present disclosure. In panel 820, various host dies 110 (with circuit regions 104) and buffer circuits 702 are mounted to a second temporary carrier substrate 822 with active layers 824 (e.g., the circuit regions 104) proximate to the second temporary carrier substrate 822. For example, panel 820 illustrates two core circuit regions 104-core, two frame circuit regions 104-frame, and two buffer circuits 702. It is noted that in this configuration, the buffer circuits 702 may be considered to be circuit regions 104 (e.g., on host dies 110), but reference numbers from FIG. 7E are maintained for consistency of illustration. The core circuit regions 104-core, the frame circuit regions 104-frame, and the buffer circuits 702 may be mounted using any technique known in the art including, but not limited to, a stack-to-wafer process. In panel 826, backsides of the host dies 110 including the core circuit regions 104-core, the frame circuit regions 104-frame, and the buffer circuits 702 are planarized.

FIG. 8C is a third sequence of side-view panels depicting fabrication of the macrochip 100 illustrated in FIG. 7E, in accordance with one or more embodiments of the present disclosure. In panel 828, the planarized backsides of the host dies 110 (e.g., including the core circuit regions 104-core, the frame circuit regions 104-frame, and the buffer circuits 702) are mounted to the carrier plane 818 exposed in panel 816. Further, various electrical connections may be made between the HBM component stacks 106-1 and the buffer circuits 702. For example, panel 828 depicts direct copper bonds 830 providing connectivity between at least the HBM component stacks 106-1 and the buffer circuits 702. In panel 832, the second temporary carrier substrate 822 is removed to expose the active layers 824 of the host dies 110. In this way, the panel 832 depicts a host substrate 102. In panel 834, additional HBM component stacks 106-2 and an interconnect stack 108 are mounted to the host substrate 102 to form the macrochip 100 of FIG. 7E. The additional HBM component stacks 106-2 and the interconnect stack 108 may be mounted using any technique known in the art including, but not limited to, a stack-to-wafer process. In this way, panel 834 may be similar to FIG. 5 and the descriptions of FIG. 5 may be extended to panel 834.

Referring generally to FIGS. 7E-8B, it is to be understood that FIGS. 7E-8B and the associated description are not limiting on the present disclosure. For example, techniques for multi-layer memory illustrated in FIG. 7E-8B may be extended to, but are not limited to, any of the implementations illustrated in FIGS. 7A-7D.

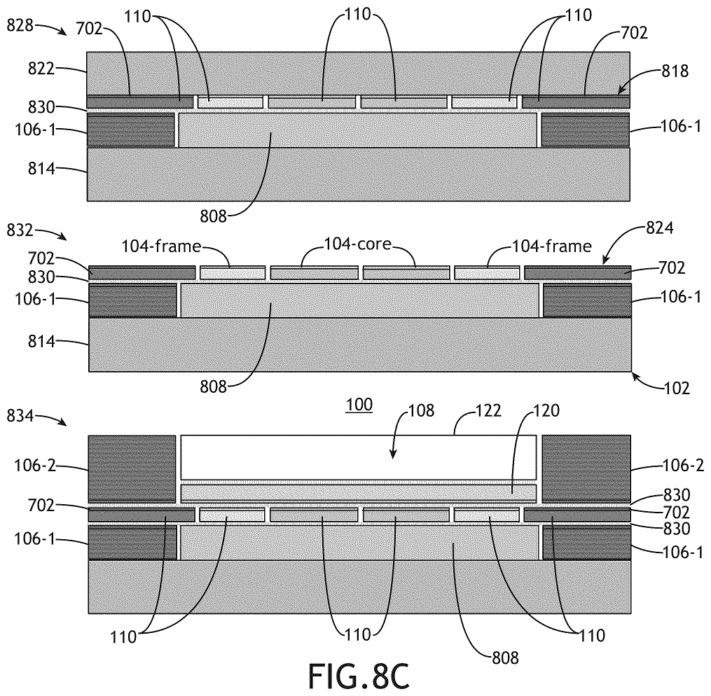

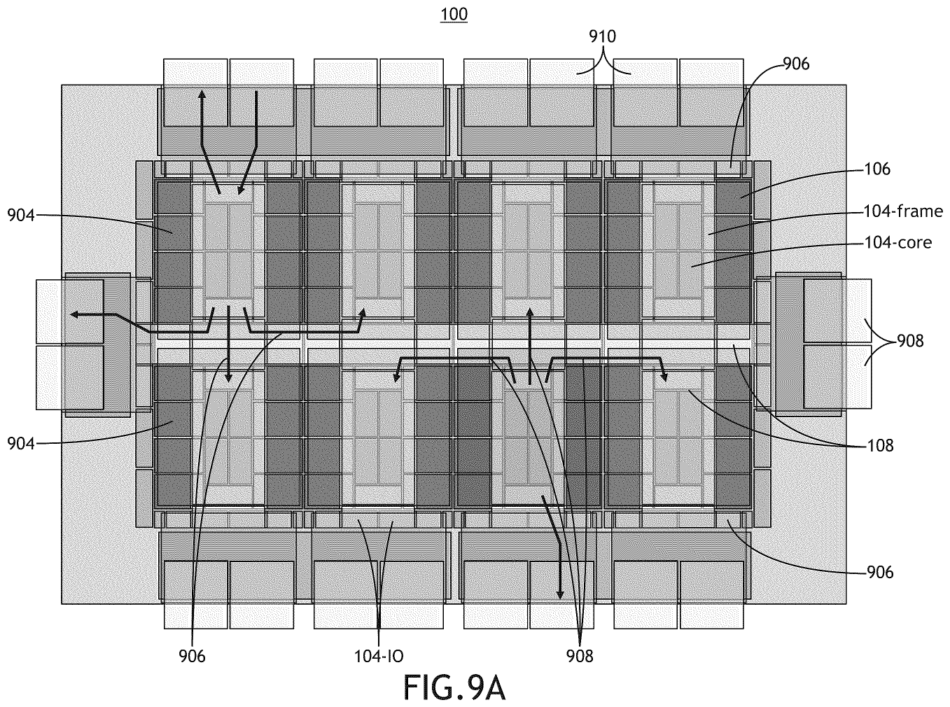

Referring now to FIG. 9A-9B, a non-limiting example of a macrochip 100 formed from multiple computational nodes as illustrated in FIG. 6 is described, in accordance with one or more embodiments of the present disclosure.

FIG. 9A is a top view 902 of a macrochip 100 formed from multiple computational nodes as illustrated in FIG. 6, in accordance with one or more embodiments of the present disclosure. In particular, the macrochip 100 in FIG. 9A includes eight computational nodes 904, each having the design illustrated in FIG. 6 with several variations. For example, that each computational node 904 includes four core circuit regions 104-core rather than one as illustrated in FIG. 6. As another example, the computational nodes 904 only have I/O circuit region 104-IO directly connected to IWVs 122 on outer edges 906. Third, the macrochip 100 includes additional interconnect stacks 108 to connect the various computational nodes 904. As another example, FIG. 9A illustrates various non-limiting communication pathways 908 between the computational nodes 904.

The macrochip 100 in FIG. 9A further includes I/O modules 910 attached to the IWVs 122 that are connected to the I/O circuit region 104-IO to facilitate high-speed communication to and from the macrochip 100. FIG. 9B includes a section of FIG. 9A at increased magnification to illustrate the I/O modules in greater detail, in accordance with one or more embodiments of the present disclosure. FIG. 9B further includes an inset 912 including a side view of the macrochip 100 based on cut-line 914 and an inset 916 including a side view of the macrochip 100 based on cut-line 918. Additionally, FIG. 9B depicts various power network components 920 (e.g., decoupling capacitors, voltage regulators, or the like) on the PCBs 132 associated with each computational node 904. It is noted that the various components illustrated in FIGS. 9A and 9B may also be provided on a macrochip 100 with a single computational node 904 (e.g., as illustrated in FIG. 6) as well as any of the depictions in FIGS. 1C and 1D. In this way, the illustrations of various higher-level system components in FIGS. 9A and 9B are merely illustrative and not limiting for any particular implementation.

As depicted in FIGS. 9A and 9B, an I/O module 910 may include a PCB 132 in the secondary plane 130 to connect to the IWVs 122 to access the I/O circuit region 104-IO. As an illustration, FIG. 9B depicts electrical pathways 922 from the I/O modules through the IWVs 122 to the I/O modules. An I/O module 910 may further include various additional components to facilitate communication to and from the macrochip 100. For example, FIGS. 9A and 9B illustrate I/O modules with an electrical integrated circuit (EIC) 924 including electrical driving and receiving circuitry, a photonic integrated circuit (PIC) 926 providing an optical to electrical interface, and a fiber connector 928 to provide a connection to an optical fiber (not shown).

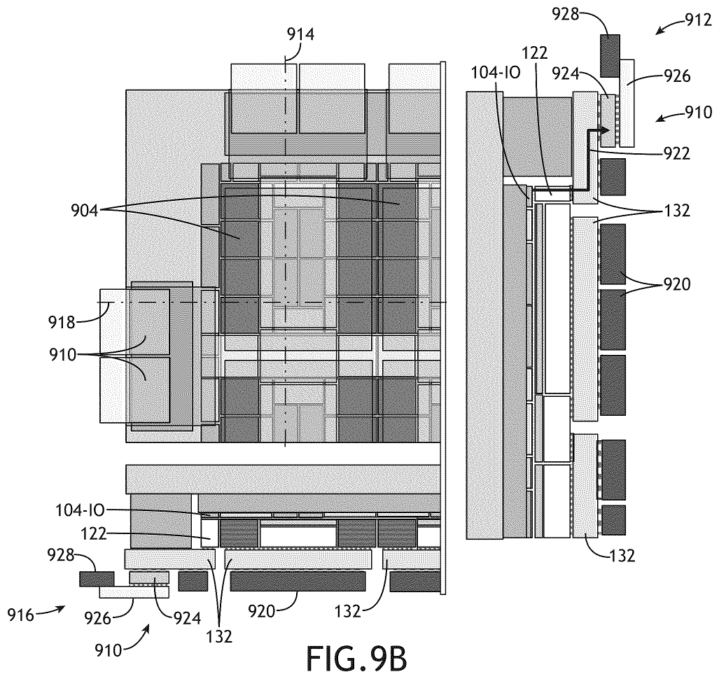

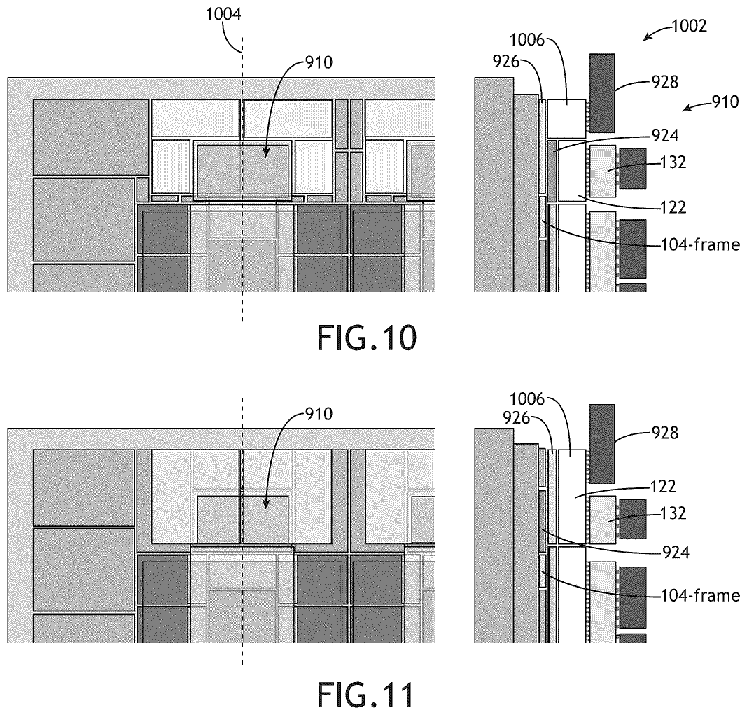

It is to be understood that a macrochip 100 may include any type of I/O modules known in the art and that the particular illustrations are not limiting on the present disclosure. FIGS. 10 and 11 provide additional non-limiting implementations of I/O modules, in accordance with one or more embodiments of the present disclosure.

FIG. 10 is a top view of a portion of a macrochip 100 and an inset 1002 corresponding to a cut-line 1004 illustrating an I/O module 910 with an EIC 924 integrated into an interconnect die 120 of an interconnect stack 108, in accordance with one or more embodiments of the present disclosure. For example, the EIC 924 integrated into an interconnect die 120 may be bonded to an IWV 122 and may overlap a portion of a host die 110 (e.g., a frame circuit region 104-frame as illustrated in FIG. 10) to facilitate connections to the core circuit regions 104-core. The EIC 924 integrated into an interconnect die 120 may further overlap a PIC 926 located on the same plane as the host dies 110. The PIC 926 may thus be considered a circuit region 104 (e.g., on a host die 110). In this configuration, the I/O module 910 may include an additional insulating wafer 1006 to provide a connection to the fiber connector. For example, light associated with data to or from the macrochip 100 may propagate between the PIC 926 and the fiber connector directly through the additional insulating wafer 1006 or through an optical waveguide in the additional insulating wafer 1006. Additionally, the PIC 926 and/or the EIC 924 may receive power from the frame circuit region 104-frame or directly (e.g., from electrically-conductive vias through connected insulating wafers).

FIG. 11 is a top view of a portion of a macrochip 100 and an inset 1102 corresponding to a cut-line 1104 illustrating an I/O module 910 with an EIC 924 provided as an circuit region 104 (e.g., on a host die 110), in accordance with one or more embodiments of the present disclosure. For example, the EIC 924 may receive electrical signals from an overlapping interconnect die 120 of an adjacent interconnect stack 108. In some embodiments, a PIC 926 is integrated into an interconnect die 120 of an interconnect stack 108 and connected to the EIC 924. In this way, light may travel between the PIC 926 and a fiber connector in a manner similar to FIG. 10.

In some embodiments, though not shown, both an EIC 924 and a PIC 926 are provided as host dies 110 and connected via an interconnect stack 108.

Referring generally to FIGS. 9A-11, it is contemplated herein that the carrier wafer 112 of the host substrate 102 may operate as a heat sink. Accordingly, providing the EIC 924 and/or a PIC 926 may facilitate efficient cooling of the associated components.

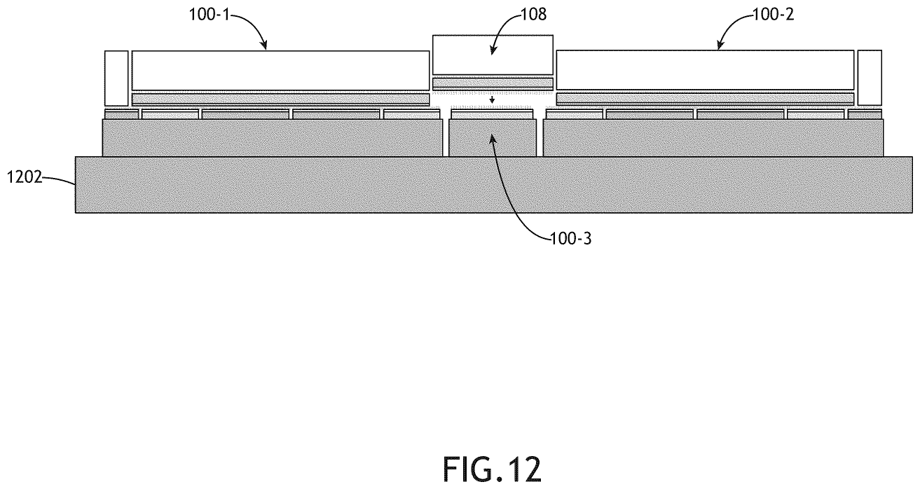

Referring now to FIG. 12, it is contemplated herein that the systems and methods disclosed herein may enable modular construction of multiple macrochips 100 to form a single combined macrochip 100. In this way, the individual macrochips 100 may be separately tested and/or verified prior to assembly in the final package. FIG. 12 is a side view of a macrochip 100 including two sub-macrochips 100-1,100-2 on a common platen 1202 that are connected by a connector sub-macrochip 100-3 including a frame circuit region 104-frame and an interconnect stack 108 to connect the sub-macrochips 100-1,100-2, in accordance with one or more embodiments of the present disclosure. It is recognized herein that such a configuration may require pre-formed bond pads 1204 (e.g., direct copper bond pads) on the connector sub-macrochip 100-3, co-planarity of the various host dies 110 across sub-macrochips 100-1,100-2, 100-3, and possibly a tolerant bonding technique. However, such a configuration may increase the yield of the final combined macrochip 100.

Referring generally to FIGS. 6-12, although FIGS. 6-12 and the associated descriptions depict implementations of a macrochip 100 based on a reconstituted host substrate 102 having various host dies 110, it is to be understood that this is merely illustrative and not limiting on the present disclosure. Rather, the systems and methods disclosed herein may be extended to other geometries including, but not limited to, a macrochip 100 based on a monolithic host substrate 102. In this way, the various circuit regions 104 in FIGS. 6-12 (e.g., the core circuit regions 104-core, the frame circuit regions 104-frame, the I/O circuit region 104-IO, or the like) may alternatively be implemented as different circuit regions 104 on a monolithic host substrate 102.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A device comprising:
a host substrate including two or more circuit regions;
one or more first stacks, each of the one or more first stacks including one or more electrical components on one or more layers, each of the one or more first stacks electrically connected to at least one of the two or more circuit regions on the host substrate; and
one or more second stacks providing electrical connections between the two or more circuit regions, the one or more second stacks further providing electrical power to the two or more circuit regions, wherein at least some of the second stacks include an insulator wafer bonded to a die, the die further connected to at least one of the two or more circuit regions;
wherein at least one of the one or more second stacks includes a first electrical pathway to provide the electrical power to at least one of the two or more circuit regions, the first electrical pathway including an electrically-conductive via through the insulator wafer and at least one of an electrically-conductive via through the die or a capacitor in the die; and
wherein the die of at least one of the one or more second stacks includes one or more second electrical pathways to provide electrical connections between at least two of the two or more circuit regions.

2. The device of claim 1, wherein the insulator wafer of at least one of the one or more second stacks comprises glass.

3. The device of claim 1, wherein the die of at least one of the one or more second stacks comprises one or more patterned semiconductor layers.

4. The device of claim 1, wherein the one or more second stacks and the one or more first stacks are electrically connected to the host substrate using direct copper bonds.

5. The device of claim 1, wherein the die of at least one of the one or more second stacks comprises passive electrical elements.

6. The device of claim 5, wherein the die of at least one of the one or more second stacks further incudes at least one active electrical element.

7. The device of claim 1, wherein the host substrate is formed from a monolithic wafer.

8. The device of claim 1, wherein the host substrate is formed from a reconstituted wafer including a carrier wafer and two or more host dies, wherein the two or more circuit regions are distributed between the two or more host dies.

9. The device of claim 1, wherein the capacitor in the die comprises a deep trench capacitor.

10. The device of claim 1, further comprising:
at least one of a printed circuit board or an interposer located in a secondary plane and connected to faces of at least some of the one or more first stacks or the one or more second stacks opposite the host substrate.

11. The device of claim 10, further comprising:
circuitry in the secondary plane to provide power to the two or more circuit regions through at least one of the one or more second stacks.

12. The device of claim 10, wherein at least one of the one or more first stacks comprises a stacked memory device, wherein at least one of the two or more circuit regions comprises a core IC with logic circuitry, wherein the device operates as a computing device.

13. A method comprising:
fabricating a host substrate including two or more circuit regions;
fabricating one or more first stacks, each of the one or more first stacks including one or more electrical components on one or more layers;
connecting the one or more first stacks to at least one of the two or more circuit regions;
fabricating one or more second stacks, wherein at least some of the second stacks include an insulator wafer bonded to a die; and
connecting the one or more second stacks to the host substrate, wherein at least one of the one or more second stacks includes a first electrical pathway to provide electrical power to at least one of the two or more circuit regions, the first electrical pathway including an electrically-conductive via through the insulator wafer and at least one of an electrically-conductive via through the die or a capacitor in the die, wherein at least one of the one or more second stacks includes a second electrical pathway to provide electrical connections between at least two of the two or more circuit regions.

14. The method of claim 13, wherein at least one of connecting the one or more first stacks to at least one of the two or more circuit regions or connecting the one or more second stacks the host substrate are implemented using direct copper bonding.

15. A device comprising:
two or more computational nodes, at least some comprising:
a host substrate including two or more circuit regions;
one or more first stacks, each of the one or more first stacks including one or more electrical components on one or more layers, each of the one or more first stacks electrically connected to at least one of the two or more circuit regions on the host substrate;
one or more second stacks providing electrical connections between the two or more circuit regions, the one or more second stacks further providing electrical power to the two or more circuit regions, wherein at least some of the second stacks include an insulator wafer bonded to a die, the die further bonded to at least one of the two or more circuit regions;
wherein at least one of the one or more second stacks includes a first electrical pathway to provide the electrical power to at least one of the two or more circuit regions, the first electrical pathway including an electrically-conductive via through the insulator wafer and at least one of an electrically-conductive via through the die or a capacitor in the die; and
wherein the die of at least one of the one or more second stacks includes one or more second electrical pathways to provide electrical connections between at least two of the two or more circuit regions; and
one or more additional second stacks providing electrical connections between the two or more computational nodes, at least some of the one or more additional second stacks including an additional insulator wafer bonded to an additional die, wherein the additional die provides electrical connections between selected circuit regions of at least two of the two or more computational nodes.

16. The device of claim 15, wherein the one or more second stacks and the one or more first stacks are electrically connected to the host substrate using direct copper bonds.

17. The device of claim 15, wherein at least one of the two or more computational nodes comprises:
at least one of the constituent one or more first stacks formed as a stacked memory device; and
at least one of the constituent circuit regions formed as a core IC with logic circuitry.

18. The device of claim 17, wherein the at least one of the two or more computational nodes further comprises:
at least one of the constituent circuit regions formed as a frame IC with routing circuitry.

19. The device of claim 15, further comprising:
at least one of a printed circuit board or an interposer located in a secondary plane and connected to faces of at least some of the one or more first stacks or the one or more second stacks opposite the host substrate.

20. The device of claim 19, further comprising:
circuitry in the secondary plane to provide power to the two or more circuit regions through at least one of the one or more second stacks.
